(19) United States
(12) Patent Application Publication
(10) Pub. No.: US 2020/0024767 A1
(43) Pub. Date: Jan. 23, 2020

(54) SYSTEMS AND METHODS FOR BINARY SINGLE-CRYSTAL GROWTH

(71) Applicant: GM Global Technology Operations LLC, Detroit, MI (US)

(72) Inventors: Zhongyi Liu, Troy, MI (US); Louis G. Hector, JR., Shelby Township, MI (US); Xiaosong Huang, Novi, MI (US); Nicholas P. Pieczonka, Windsor (CA); Ingrid A. Rousseau, Clawson, MI (US); Michael K. Carpenter, Troy, MI (US)

(73) Assignee: GM Global Technology Operations LLC, Detroit, MI (US)

(21) Appl. No.: 16/040,035

(22) Filed: Jul. 19, 2018

(51) Int. Cl. C30B 7/14; C30B 29/40; C01B 21/06

(52) U.S. Cl. CPC C30B 7/14; C01B 21/0632; C30B 29/406

(57) ABSTRACT

Systems and methods for growth of multi-component single crystals are described. A first solution is flowed over a surface of a seed crystal coupled to a nozzle such that a plurality of first ions solvated in the first solution and a plurality of second ions in a second solution combine on the surface of the seed crystal to grow the single-crystal thereon. The first solution and the second solution are immiscible. A feed tank is fluidly coupled to the at least one nozzle and includes the first solution. In some aspects, the nozzle is configured to flow both the first solution and the second solution over the seed crystal.

### INTRODUCTION

The disclosure relates to the field of binary single-crystals and, more specifically, to systems and methods for growth of binary single-crystals, such as gallium nitride.

Binary single-crystals, including group III-V crystals, such as gallium nitride (GaN), are attractive semiconductors for their electronic characteristics. However, growing a bulk crystal from these groups is difficult. Particularly, forming a bulk crystal of GaN is difficult due to a higher dissociation pressure of nitrogen. For example, one method of forming a bulk crystal of GaN is to form a molten sodium-gallium (Na/Ga) melt held under 100 atmospheres of pressure of nitrogen gas (N₂) at 750° C. or greater, which is then reacted with ammonia or other chemicals. Alternatively, another method of forming a bulk crystal of GaN is to inject ammonia gas into molten gallium at 900-980° C. at normal atmospheric pressure. While these processes produce crystals having a low dislocation density, use of GaN semiconductors may be economically prohibitive due to the required energy, material, and capital investments to produce these crystals.

### SUMMARY

It is desirable to provide techniques for rapid growth of binary single-crystals, to optimize the cost of crystal production, and to provide for production of large format binary single-crystals. Beneficially, systems and methods in accordance with the present disclosure provide for rapid growth, low temperature and low pressure processes which use materials that are stable for extended periods of time.

According to aspects of the present disclosure, a system includes a feed tank, a crystal-growth vessel, and a pump. The feed tank fluidly stores therein a first solution with a plurality of first ions solvated in the first solution. The crystal-growth vessel includes at least one nozzle therein. The at least one nozzle is fluidly coupled to the feed tank. The at least one nozzle is configured to flow the first solution over a surface of a seed crystal coupled to the at least one nozzle such that the plurality of first ions solvated in the first solution and a plurality of second ions in a second solution combine on the surface of the seed crystal to grow a binary single-crystal thereon. The first solution and the second solution are immiscible. The pump is configured to flow the first solution from the feed tank to the crystal-growth vessel via the at least one nozzle.

According to further aspects of the present disclosure, the pump is a vacuum pump fluidly coupled to the crystal-growth vessel.

According to further aspects of the present disclosure, the binary single-crystal is gallium nitride.

According to further aspects of the present disclosure, the crystal-growth vessel includes therein a pool of the second solution, the second solution wets the surface of the seed crystal through capillary action, and the binary single-crystal grows via combining the plurality of first ions with the plurality of second ions at an interface between the first solution, the second solution, and the surface of the seed crystal.

According to further aspects of the present disclosure, the feed tank includes therein the second solution, the at least one nozzle is further configured to flow the second solution over the surface of the seed crystal simultaneously with flow of the first solution, and growth of the binary single-crystal is via combining the plurality of first ions with the plurality of second ions at an interface between the first solution, the second solution, and the surface of the seed crystal through preferential vaporization of one of the first solution and the second solution.

According to further aspects of the present disclosure, the system is configured to maintain a temperature less than about 300° C. proximate to the binary single-crystal.

According to aspects of the present disclosure, a method for growth of a binary single-crystal, the method includes providing a seed crystal, supplying a first solution to a surface of the seed crystal, wetting the seed crystal with a second solution, and growing the binary single-crystal via combining the plurality of first ions with the plurality of second ions at an interface between the first solution, the second solution, and the surface of the seed crystal. The first solution contains a plurality of first ions solvated therein, and the second solution contains a plurality of second ions solvated therein. The first solution and the second solution are immiscible.

According to further aspects of the present disclosure, wetting includes contacting an end of the seed crystal with a pool of the second solution, and the second solution has a second density that is less than a density of the first solution.

According to further aspects of the present disclosure, the binary single-crystal is gallium nitride.

According to further aspects of the present disclosure, the first solution includes an ionic solution and the second solution includes an organic solvent.

According to further aspects of the present disclosure, the seed crystal is provided within a crystal-growth vessel under vacuum.

According to further aspects of the present disclosure, growing the binary single-crystal is carried out at less than about 300° C.

According to aspects of the present disclosure, a method for binary single-crystal growth, the method includes providing a seed crystal, flowing a two-component mixture over a surface of the seed crystal, and growing a binary single-crystal via preferential vaporization of one of a first solution and a second solution to thereby combine a plurality of first ions with a plurality of second ions at an interface between the first solution, the second solution, and the surface of the seed crystal. The two-component mixture includes the first solution and the second solution. The first solution and the second solution are immiscible. The first solution contains the plurality of first ions solvated therein, and the second solution contains the plurality of second ions solvated therein. The first solution and the second solution have different vapor pressures.

According to further aspects of the present disclosure, the binary single-crystal is gallium nitride.

According to further aspects of the present disclosure, the first solution includes an ionic liquid and the second solution includes an organic solvent.

According to further aspects of the present disclosure, the seed crystal is provided within a crystal-growth vessel under vacuum.

According to further aspects of the present disclosure, growing the binary single-crystal is carried out at less than about 300° C.

According to aspects of the present disclosure, a mixture includes a first solution and a second solution. The first solution includes an ionic liquid with an azolium salt and a metallic nitride solvated within the ionic liquid. The second solution includes an organic liquid with gallium cations solvated therein.

According to further aspects of the present disclosure, the azolium salt has a diazolium cation.

According to further aspects of the present disclosure, the azolium salt has a 1-butyl-3-methylimidazolium cation.

According to further aspects of the present disclosure, the azolium salt has a superhalogen anion.

According to further aspects of the present disclosure, the azolium salt has a fluorine-containing superhalogen anion.

According to further aspects of the present disclosure, the first solution further includes an organic solvent. The organic solvent and the ionic liquid are miscible, and the organic solvent has a boiling point below 300° C.

According to further aspects of the present disclosure, the first solution further includes a glycol ether configured to solvate a cation of the metallic nitride. The glycol ether is miscible within the ionic liquid.

According to further aspects of the present disclosure, the first solution further includes a volatile solvent, and the evaporation of the volatile solvent will increase the metallic nitride concentration in the first solution.

The above features and advantages and other features and advantages of the present disclosure are readily apparent from the following detailed description of representative modes for carrying out the disclosure when taken in connection with the accompanying drawings and the appended claims.

### BRIEF DESCRIPTION OF THE DRAWINGS

The drawings are illustrative and not intended to limit the subject matter defined by the claims. Exemplary aspects are discussed in the following detailed description and shown in the accompanying drawings in which:

FIG. 1 is a schematic illustration of a representative system for growth of a binary single-crystal, according to some aspects of the present disclosure;

FIG. 2 is another schematic illustration of the representative system of FIG. 1, according to some aspects of the present disclosure;

FIG. 3 is yet another schematic illustration of the representative system of FIG. 1, according to some aspects of the present disclosure;

FIG. 4 is a flowchart of a method of growing a binary single-crystal, according to some aspects of the present disclosure; and

FIG. 5 is a flowchart of a method of growing a binary single-crystal, according to some aspects of the present disclosure.

### DETAILED DESCRIPTION

Systems and methods in accordance with the present disclosure provide for rapid growth of binary single-crystals, optimize the cost of production, and are capable of producing large format binary single-crystals. For example, throughput of systems and methods in accordance with the present disclosure may produce 50 mm wafers at a throughput that is at least about 10 to 100 times greater than existing processes for growth of binary single-crystals. What is more, 50 mm wafers may be produced by systems and methods in accordance with the present disclosure at about 5% of the cost of similar wafers produced by existing binary crystal-growth processes. Yet further, the boule grown by systems and methods in accordance with the present disclosure may create wafers having diameters of such as at least 1″, 2″, or 4″ diameter wafers.

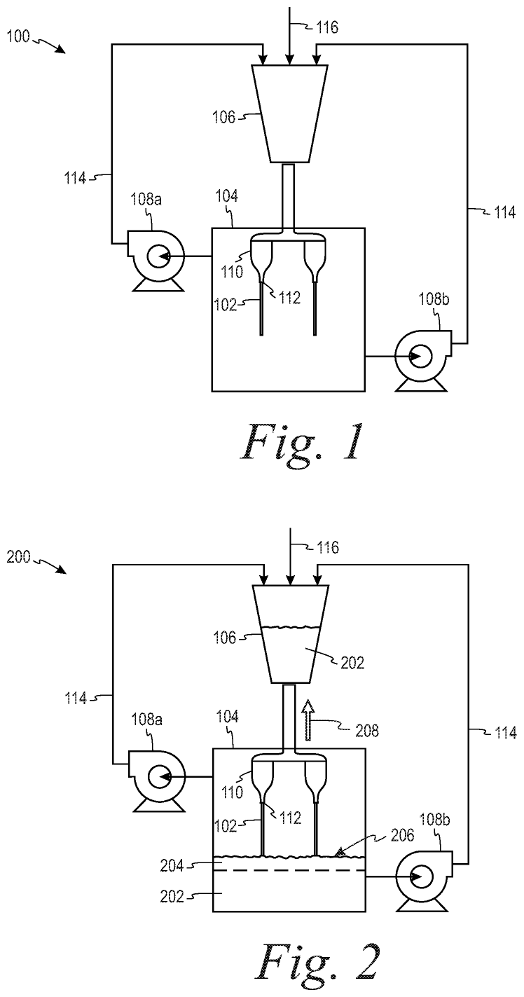

Referring now to FIG. 1, a system 100 for growth of a binary single-crystal 102 is shown. The system 100 includes a crystal-growth vessel 104, a feed tank 106, and at least one pump 108a,b. The crystal-growth vessel 104 maintains conditions to facilitate growth of at least one binary single-crystal 102 therein.

The crystal-growth vessel 104 includes at least one nozzle 110 therein. Each nozzle 110 flows liquid over a seed crystal 112 coupled to the respective nozzle 110. The seed crystal 112 is a binary crystal having the desired crystalline structure of the binary single-crystal 102.

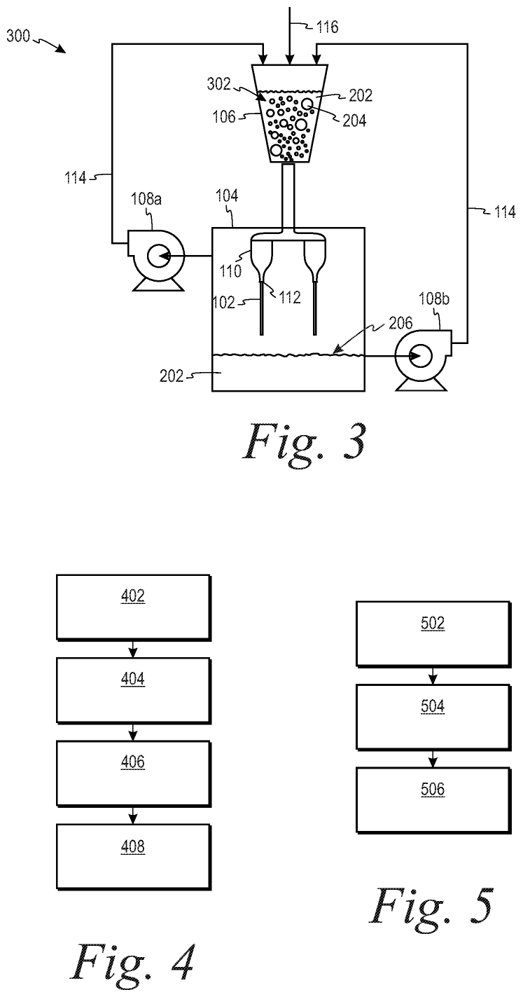

The binary single-crystal 102 is formed by a plurality of first ions in a first solution 202 (FIGS. 2 and 3) and a plurality of second ions in a second solution 204 (FIGS. 2 and 3) combine on a surface of the seed crystal 112 such that the binary single-crystal 102 extends axially from the nozzle 110. The first solution 202 and the second solution 204 are immiscible. In some aspects, the first solution 202 and the second solution 204 are provided in a two-component mixture 302 (FIG. 3) that is then supplied to the seed crystal 112.

The first solution 202 includes an ionic liquid capable of solvating a solute providing the plurality of first ions. In some aspects, the solute is a metallic nitride. For example, the metallic nitride may be lithium nitride (Li₃N).

The ionic liquid of the first solution 202 may be selected for thermal stability and low viscosity. The selected ionic liquid may be thermally stable at 100° C. or above for extended periods of time, such as a week, to provide for cost-effective storage and preparation of the first solution 202. The low viscosity may be below about 20,000 centipoise (CPS) at the process conditions to optimize flow properties and provide for even coating of the seed crystal 112. The first solution 202 may include compatible additives to decrease viscosity of the pure form of the ionic liquid while maintaining immiscibility with the second solution 204.

In some aspects, the ionic liquid is an azolium salt. The azolium salt may include a diazolium cation. The diazolium cation may be 1-butyl-3-methylimidazolium cation. Beneficially, ionic liquids including 1-butyl-3-methylimidazolium provide thermal stability at elevated temperatures for extended periods of time, such as about one week. The azolium salt may further include a superhalogen anion. The superhalogen anion may be a fluorine-containing superhalogen anion. The superhalogen anion may be tetrafluoroborate (BF₄⁻) or hexafluorophosphate (PF₆⁻)

In some aspects, the first solution further includes one or more additional solvents to increase solubility of the solute. The additional solvents are miscible with the ionic liquid. The additional solvents may have a low boiling point (such as volatile solvents), an increased affinity for the cation of the metallic nitride, or both. As used herein, the term low boiling point means that the boiling point of the solvent used is below the process temperature, e.g., below 300° C. While not being bound by theory, it is believed that the additional solvent and evaporation thereof increases solubility and concentration of the metallic nitride. For example, the additional solvent may be methyl ethyl ketone. As also used herein, an increased affinity for the cation of the metallic nitride means that the additional solvent increases solubility of the metallic nitride by improving interactions with the cation. For example, the additional solvent may be selected for its ability to preferentially form complexes with the cation of the metallic nitride. In some aspects, the additional solvent is a glycol ether, such as glyme.

The second solution 204 includes an organic liquid capable of solvating a solute providing the plurality of second ions. In some aspects, the second solution 204 is an organic liquid with a gallium salt dissolved therein. For example, the gallium salt may be gallium chloride (GaCl₃) and the organic liquid may be any suitable organic solvent that is immiscible with the first solution 202. Surprisingly, the organic liquid may be an alkane such as pentane.

The feed tank 106 is fluidly coupled to one or more of the nozzles 110 within the crystal-growth vessel 104. The feed tank 106 includes the first solution 202 therein. In some aspects, such as that shown in FIG. 3, the feed tank 106 also includes the second solution 204 therein. The feed tank may also include a stirrer to mix the liquids therein prior to flow through the nozzle 110.

The pump 108a,b is configured to flow the first solution 202 from the feed tank 106 to the crystal-growth vessel 104 via the at least one nozzle 110. In some aspects, the pump 108a,b is a vacuum pump 108a fluidly coupled to the crystal-growth vessel 104. In some aspects, the pump 108a,b is a recycle pump 108b fluidly coupled to the crystal-growth vessel 104 and the feed tank 106.

In some aspects, the binary single-crystal 102 is gallium nitride, the plurality of first ions is either gallium ions or nitride ions, and the plurality of second ions is the other of gallium ions or nitride ions. In some aspects, the binary single-crystal 102 and the seed crystal 112 are rotated, spun, or both during growth of the binary single-crystal 102. While not being bound by theory, it is believed that rotation and/or spinning of the seed crystal 112 reduces defects in the binary single-crystal 102 by promoting uniformity of the interface between the first solution 202 and the second solution 204 throughout growth.

The binary single-crystal 102 may be grown at a temperature less than about 300° C. In some aspects, the binary single-crystal 102 is grown at a temperature less than about 200° C. In some aspects, the binary single-crystal 102 is grown at a temperature less than about 100° C.

One or more recycle streams 114 may be included to direct fluids from the crystal-growth vessel 104 to the feed tank 106. The fluids may be the first solution 202, the second solution 204, or both.

One or more feed streams 116 may be coupled to the feed tank 106 and/or the crystal-growth vessel 104. The one or more feed streams 116 are used to increase the concentration of the plurality of first ions, the plurality of second ions, or both in the feed tank 106 and/or the crystal-growth vessel 104.

Referring now to FIG. 2, a system 200 for growth of the binary single-crystal 102 is shown. The crystal-growth vessel 104 of the system 200 includes the second solution 204 in a pool 206.

The second solution 204 wets the surface of the seed crystal 112 through capillary action. An end of the binary single-crystal 102 contacts the pool 206 of the second solution 204 such that a meniscus of the second solution 204 forms around the end of the binary single-crystal 102. The meniscus is formed by capillary action drawing the second solution 204 a distance up the surface of the binary single-crystal 102. The nozzle 110 is configured to be translated upwardly and away from the pool 206, as indicated by arrow 208, during growth of the binary single-crystal 102 at a rate that maintains the meniscus and facilitates continued growth of the binary single-crystal 102.

Combining the plurality of first ions with the plurality of second ions at an interface between the first solution 202, the second solution 204, and the surface of the seed crystal 112 is promoted by the interaction between the meniscus of the second solution 204 and flow of the first solution 202.

The second solution 204 is less dense than the first solution 202. Beneficially, the difference in density allows the upper portion of the pool 206 to be rich in the second solution 204 without being substantially diluted by flow of the first solution 202 down the binary single-crystal 102. Further, the difference in density allows the lower portion of the pool 206 to be rich in the first solution 202, which can then be recycled to the feed tank 106 via recycle stream 114 without significant contamination of the feed tank 106 by the second solution 204.

Referring now to FIG. 3, a system 300 for growth of the binary single-crystal 102 is shown. The feed tank 106 of system 300 further includes the second solution 204 therein to form the two-component mixture 302. The nozzle 110 is further configured to flow the second solution 204 over the surface of the seed crystal 112 simultaneously with flow of the first solution 202. The nozzle 110 may be translated or may remain stationary during growth of the binary single-crystal 102.

Combining the plurality of first ions with the plurality of second ions at an interface between the first solution 202, the second solution 204, and the surface of the seed crystal 112 is promoted by preferential vaporization of one of the first solution 202 and the second solution 204.

Referring now to FIG. 4, a method for growth of the binary single-crystal 102 is shown. The method includes providing 402 the seed crystal 112, supplying 404 the first solution 202 to the surface of the seed crystal 112, wetting 406 the seed crystal 112 with the second solution 204, and growing 408 the binary single-crystal 102.

The growth of the binary single-crystal 102 occurs via combining the plurality of first ions with the plurality of second ions at an interface between the first solution 202, the second solution 204, and the surface of the seed crystal 112.

In some aspects, wetting 406 the seed crystal 112 includes contacting an end of the seed crystal 112 with a pool 206 of the second solution 204.

Referring now to FIG. 5, a method for binary single-crystal 102 growth is shown. The method includes providing 502 the seed crystal 112, flowing 504 the two-component mixture 302 over the surface of the seed crystal 112, and growing 506 the binary single-crystal 102.

The two-component mixture 302 includes the first solution 202 and the second solution 204, which are immiscible. Further, the first solution 202 and the second solution 204 have different vapor pressures.

Growth of the binary single-crystal 102 occurs via preferential vaporization of one of the first solution 202 and the second solution 204. The preferential vaporization promotes combining of the plurality of first ions with the plurality of second ions at an interface between the first solution 202, the second solution 204, and the surface of the seed crystal 112.

Systems and methods as described herein provide for rapid growth, high yield, and reduced cost of binary single-crystals 102 such as gallium nitride. In some aspects, a 10-liter system with a nitride concentration of 0.5 M and a flowrate of 0.7 L/hr may produce a 50 mm wafer at a rate of about 10 mm/hr. Moreover, the yield of the system may reach about 3 kg/day at a forecasted cost of about $100 per wafer.

While the present disclosure discusses growth of binary single-crystals 102, systems and methods in accordance with the present disclosure may be used to grow multi-component single-crystals such as ternary single-crystals and the like. For example, a plurality of third ions may be provided in the first solution 202, the second solution 204, or a third solution that is immiscible with the first solution 202 and the second solution 204.

While the best modes for carrying out the disclosure have been described in detail, those familiar with the art to which this disclosure relates will recognize various alternative designs and embodiments for practicing the disclosure within the scope of the appended claims.

What is claimed is:

1. A system comprising:
a feed tank fluidly storing therein a first solution with a plurality of first ions solvated in the first solution;
a crystal-growth vessel including at least one nozzle therein, the at least one nozzle being fluidly coupled to the feed tank, the at least one nozzle configured to flow the first solution over a surface of a seed crystal coupled to the at least one nozzle such that the plurality of first ions solvated in the first solution and a plurality of second ions in a second solution combine on the surface of the seed crystal to grow a binary single-crystal thereon, the first solution and the second solution being immiscible; and
a pump configured to flow the first solution from the feed tank to the crystal-growth vessel via the at least one nozzle.

2. The system of claim 1, wherein the pump is a vacuum pump fluidly coupled to the crystal-growth vessel.

3. The system of claim 1, wherein the binary single-crystal is gallium nitride.

4. The system of claim 1, wherein the crystal-growth vessel includes therein a pool of the second solution, wherein the second solution wets the surface of the seed crystal through capillary action, and wherein the binary single-crystal grows via combining the plurality of first ions with the plurality of second ions at an interface between the first solution, the second solution, and the surface of the seed crystal.

5. The system of claim 1, wherein the feed tank includes therein the second solution, wherein the at least one nozzle is further configured to flow the second solution over the surface of the seed crystal simultaneously with flow of the first solution, and wherein growth of the binary single-crystal is via combining the plurality of first ions with the plurality of second ions at an interface between the first solution, the second solution, and the surface of the seed crystal through preferential vaporization of one of the first solution and the second solution.

6. The system of claim 1, wherein system is configured to maintain a temperature less than about 300° C. proximate the binary single-crystal.

7. A method for growth of a binary single-crystal, the method comprising:
providing a seed crystal;
supplying a first solution to a surface of the seed crystal, the first solution containing a plurality of first ions solvated therein;
wetting the seed crystal with a second solution, the second solution containing a plurality of second ions solvated therein, the first solution and the second solution being immiscible; and
growing the binary single-crystal via combining the plurality of first ions with the plurality of second ions at an interface between the first solution, the second solution, and the surface of the seed crystal.

8. The method of claim 7, wherein wetting includes contacting an end of the seed crystal with a pool of the second solution, the second solution having a second density that is less than a density of the first solution.

9. The method of claim 7, wherein the binary single-crystal is gallium nitride.

10. The method of claim 7, wherein the first solution includes an ionic solution and the second solution includes an organic solvent.

11. The method of claim 7, wherein the seed crystal is provided within a crystal-growth vessel under vacuum.

12. The method of claim 7, wherein growing the binary single-crystal is carried out at less than about 300° C.

13. A method for binary single-crystal growth, the method comprising:
providing a seed crystal;
flowing a two-component mixture over a surface of the seed crystal, the two-component mixture including a first solution and a second solution, the first solution and the second solution being immiscible, the first solution containing a plurality of first ions solvated therein, the second solution containing a plurality of second ions solvated therein, the first solution and the second solution having different vapor pressures; and
growing a binary single-crystal via preferential vaporization of one of the first solution and the second solution to thereby combining the plurality of first ions with the plurality of second ions at an interface between the first solution, the second solution, and the surface of the seed crystal.

14. The method of claim 13, wherein the binary single-crystal is gallium nitride.

15. The method of claim 13, wherein the first solution includes an ionic liquid and the second solution includes an organic solvent.

16. The method of claim 13, wherein the seed crystal is provided within a crystal-growth vessel under vacuum.

17. The method of claim 13, wherein growing the binary single-crystal is carried out at less than about 300° C.

18. A binary single-crystal precursor mixture comprising:
a first solution including:
an ionic liquid including an azolium salt, and a metallic nitride solvated within the ionic liquid; and
a second solution including an organic liquid with gallium cations solvated therein.

19. The mixture of claim 18, wherein the azolium salt has a diazolium cation.

20. The mixture of claim 18, wherein the azolium salt has a 1-butyl-3-methylimidazolium cation.

21. The mixture of claim 18, wherein the azolium salt has a superhalogen anion.

22. The mixture of claim 18, wherein the azolium salt has a fluorine-containing superhalogen anion.

23. The mixture of claim 18, wherein the first solution further includes an organic solvent, the organic solvent and the ionic liquid are miscible, and the organic solvent has a boiling point below 300° C.

24. The mixture of claim 18, wherein the first solution further includes a glycol ether configured to solvate a cation of the metallic nitride, the glycol ether being miscible within the ionic liquid.
